(19) United States
(12) Patent Application Publication
(10) Pub. No.: US 2008/0042131 A1
(43) Pub. Date: Feb. 21, 2008

(54) System for displaying images including thin film transistor device and method for fabricating the same

(75) Inventors: Yoshihiro Morimoto, Hsinchu City (TW); Ryan Lee, Hualien City (TW); Hanson Liu, Kaohsiung City (TW); Feng-Yi Chen, Changjhih Township (TW)

Correspondence Address: LIU & LIU, 444 S. FLOWER STREET, SUITE 1750, LOS ANGELES, CA, 90071, US

(73) Assignee: TPO Displays Corp.

(21) Appl. No.: 11/504,490

(22) Filed: Aug. 15, 2006

(51) Int. Cl. H01L 29/04

(52) U.S. Cl. 257/59

(57) ABSTRACT

A system for displaying images. The system comprises a thin film transistor (TFT) device comprising a substrate comprising a driving circuit region and a pixel region. First and second active layers are disposed on the substrate in the driving circuit region and in the pixel region, respectively. The first active layer has a grain size greater than that of the second active layer. Two gate structures are disposed on the first and second active layers, respectively, in which each gate structure comprises a stack of a gate dielectric layer and a gate layer. A reflector is disposed on the substrate under the first active layer and insulated from the first active layer. A method for fabricating a system for displaying images including the TFT device is also disclosed.

### BACKGROUND OF THE INVENTION

1. Field of the Invention

The invention relates to a flat panel display technology, and in particular to an improved thin film transistor (TFT) device having different electrical characteristics in driving circuit and pixel regions and a method for fabricating the same.

2. Description of the Related Art

The demand for active-matrix flat panel displays, such as active matrix organic light emitting device (AMOLED) displays, has increased rapidly in recent years. AMOLEDs typically employ thin film transistors (TFTs) as pixel and driving circuit switching elements which are classified as amorphous silicon (a-Si) TFTs and polysilicon TFTs according to the materials used as an active layer. Compared with a-Si TFTs, polysilicon TFTs have the advantages of high carrier mobility, high driving-circuit integration and low leakage current, and are often applied to high-speed operation applications. Thus, low temperature polysilicon (LTPS) is a novel application for FPD technology. LTPS allows for an easier IC manufacturing process, which integrates driving circuits on a glass substrate having pixels thereon, reducing the manufacturing cost.

In the LTPSTFT fabrication, the TFTs in the driving circuit region and the pixel region are fabricated at the same time and by the same process. Therefore, the TFTs in the pixel and driving circuit regions have the same electrical characteristics. In AMOLED, however, the electrical characteristics of the TFTs in the driving circuit region are different from that in the pixel region. For example, it is desirable to design driving TFTs with high carrier mobility and low sub-threshold swing, thereby providing fast response. Additionally, it is desirable to design pixel TFTs with high sub-threshold swing to increase gray scale inversion of the AMOLED, thereby providing high contrast ratio. However, it is difficult to fabricate TFTs with high sub-threshold swing for a pixel region and low sub-threshold swing and high carrier mobility for a driving circuit region because they are fabricated at the same time and by the same process.

Thus, there exists a need in the art for development of an improved thin film transistor device in which the TFTs have different electrical characteristics in the driving circuit and pixel regions, thereby providing pixel TFTs with high sub-threshold swing and driving TFTs with high carrier mobility and low sub-threshold swing.

### BRIEF SUMMARY OF THE INVENTION

A detailed description is given in the following embodiments with reference to the accompanying drawings. A system for displaying images and a method for fabricating the same are provided. An exemplary embodiment of a system for displaying images. The system comprises a thin film transistor (TFT) device comprising a substrate. The substrate comprises a driving circuit region and a pixel region. First and second active layers are disposed on the substrate in the driving circuit region and in the pixel region, respectively. The first active layer has a grain size greater than that of the second active layer. Two gate structures are disposed on the first and second active layers, respectively, in which each gate structure comprises a stack of a gate dielectric layer and a gate layer. A reflector is disposed on the substrate under the first active layer and insulated from the first active layer.

An embodiment of a method for fabricating a system for displaying images, wherein the system comprises a thin film transistor device, the method comprising providing a substrate. The substrate comprises a driving circuit region and a pixel region. A reflector is formed on the substrate of the driving circuit region. An insulating layer is formed on the substrate of the driving circuit and pixel regions to cover the reflector. An amorphous layer is formed on the insulating layer. The amorphous layer is annealed by a laser beam having a wavelength of not less than 400 nm, such that the amorphous layer is transformed into a polysilicon layer, wherein the portion of the polysilicon layer directly above the reflector has a grain size greater than that of other portions. The polysilicon layer is patterned to form a first active layer on the reflector and a second active layer on the substrate of the pixel region.

### BRIEF DESCRIPTION OF THE DRAWINGS

The invention can be more fully understood by reading the subsequent detailed description and examples with references made to the accompanying drawings, wherein:

FIGS. 1A to 1F are cross sections of an embodiment of a method for fabricating a system for displaying images incorporating a thin film transistor device.

FIG. 2 is a cross section of an embodiment of a thin film transistor device.

FIG. 3 schematically shows another embodiment of a system for displaying images.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

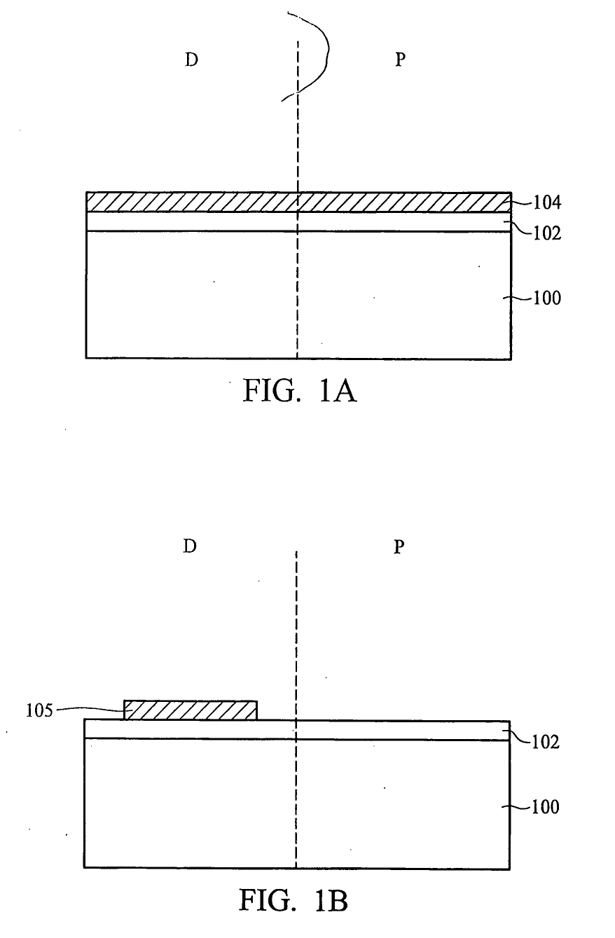

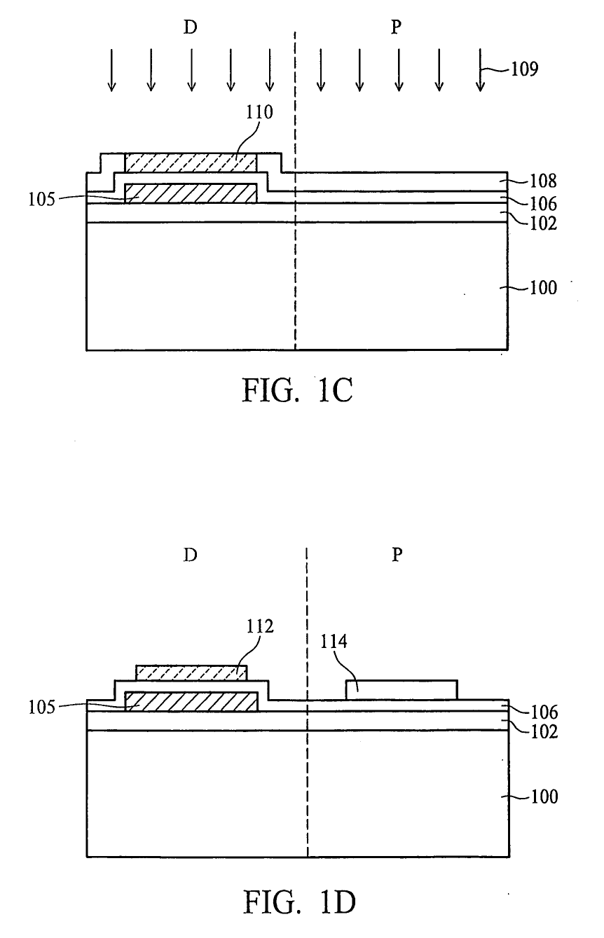

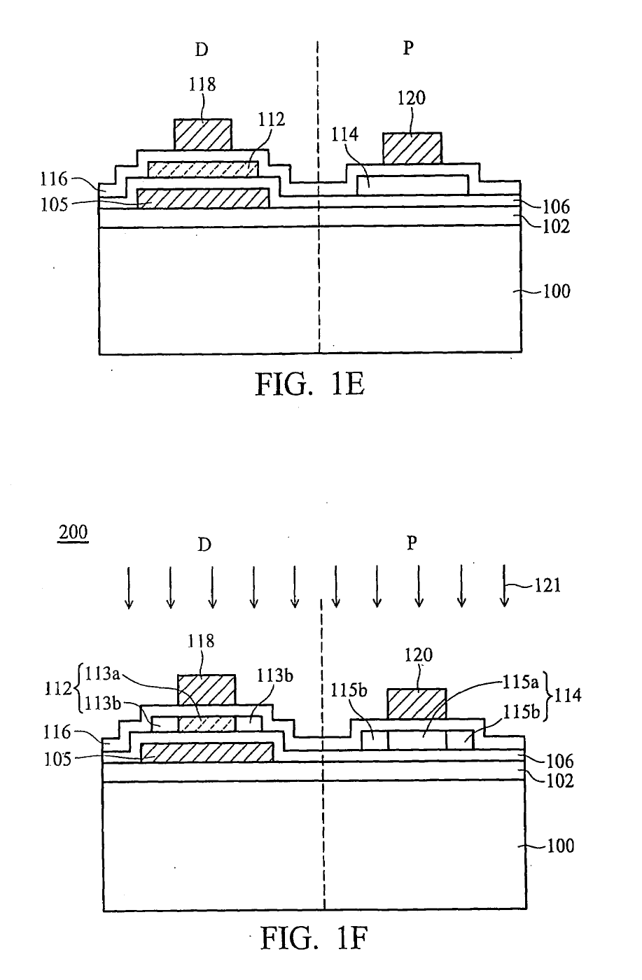

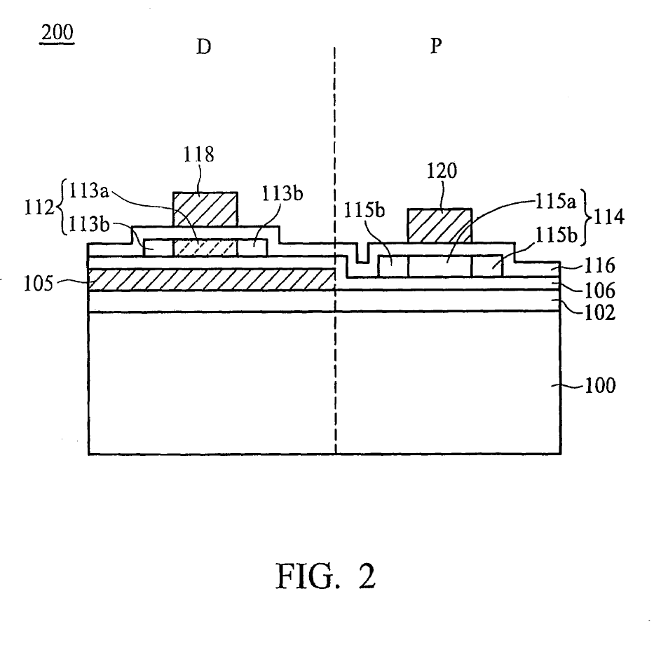

Systems for displaying images and fabrication methods for same are provided. FIGS. 1F and 2 illustrate exemplary embodiments of such a system. Specifically, the system incorporates a thin film transistor (TFT) device 200 comprising a substrate 100 comprising a driving circuit region D and a pixel region P. A buffer layer 102 may be optionally disposed on the substrate 100 to serve as an adhesion layer or a contamination barrier layer between the substrate 100 and the subsequent active layer.

A first active layer 112 is disposed on the substrate 100 of the driving circuit region D and a second active layer 114 on the substrate 100 of the pixel region P. The first active layer 112 may comprise a channel region 113a and a pair of source/drain regions 113b separated by the channel region 113a. The second active layer 114 may also comprise a channel region 115a and a pair of source/drain regions 115b separated by the channel region 115a. In this embodiment, the first and second active layers 112 and 114 may comprise low temperature polysilicon, in which the first active layer 112 has a grain size greater than that of the second active layer 114.

Fabrication of two gate structures are disposed on the first and second active layers 112 and 114, respectively, thus TFTs are complete. The TFT in the pixel region P (i.e. pixel TFT) may comprise an NMOS or a CMOS. The TFT in the driving circuit region D (i.e. driving TFT) may comprise an NMOS, a PMOS, or a CMOS. The gate structure disposed on the first active layer 112 comprises a stack of a gate dielectric layer 116 and a gate layer 118. The gate structure disposed on the active layer 114 also comprises a stack of the gate dielectric layer 116 and a gate layer 120.

A reflector 105, such as a metal layer, is disposed on the substrate 100 under the first active layer 112. Moreover, the reflector 105 is insulated from the first active layer 112 by an insulating layer 106, such as a silicon oxide, a silicon nitride or a combination thereof. In this embodiment, the first active layer 112 may be substantially aligned to the reflector 105, as shown in FIG. 1F. In some embodiments, the reflector 105 may completely cover the substrate 100 of the driving circuit region D, as shown in FIG. 2.

Referring to FIGS. 1A to 1F, which illustrate an embodiment of a method for fabricating a system for displaying images incorporating a thin film transistor device 200. In FIG. 1A, a substrate 100 comprising a driving circuit region D and a pixel region P is provided. The substrate 100 may comprise glass, quartz, or plastic. A buffer layer 102 may be optionally formed on the substrate 100 to serve as an adhesion layer or a contamination barrier layer between the substrate 100 and the subsequent layer formed thereon. The buffer layer 102 may be a single layer or multiple layers. For example, the buffer layer 102 may comprise silicon oxide, silicon nitride, or a combination thereof.

A reflective layer 104 is formed on the substrate 100. The reflective layer 104 may comprise metal, such as aluminum (Al), copper (Cu), molybdenum (Mo) or an alloy. Moreover, the reflective layer 104 may have a thickness of more than 100 Å and be formed by conventional deposition, such as sputtering or CVD.

In FIG. 1B, the reflective layer 104 is patterned by conventional lithography and etching, to form a reflector 105 on the substrate 100 of the driving circuit region D. In this embodiment, the reflector 105 is located at a region in the driving circuit region D for definition of the active layer in subsequent process steps. In some embodiments, the substrate 100 in the driving circuit region D may be completely covered by the formation of the reflector 105.

In FIG. 1C, an insulating layer 106 and an amorphous layer (not shown) are successively formed on the substrate 100 of the driving circuit and pixel region D and P to cover the reflector 105, such that the amorphous layer can be insulated from the reflector 105 by the insulating layer 106. In this embodiment, the insulating layer 106 may be a single layer or multiple layers. For example, the insulating layer 106 may comprise silicon oxide, silicon nitride, or a combination thereof.

Next, a laser annealing treatment 109 is performed on the amorphous layer, such that the amorphous silicon layer is transformed into a polysilicon layer 108. In conventional low temperature polysilicon (LTPS) fabrication, the polysilicon layer is formed by excimer laser annealing (ELA). Reduction of the sub-threshold swing of driving TFTs is, however, difficult because the grain size of the polysilicon layer formed by the excimer laser typically having a wavelength of about 248 nm to 351 nm is not large enough. Accordingly, in this embodiment, a laser beam having a wavelength of not less than 400 nm, such as a solid-state laser beam, is employed for the laser annealing treatment 109, which has better penetration than excimer laser beam for an amorphous material. Accordingly, the laser beam having a wavelength of not less than 400 nm can be repeatedly reflected from the reflector 105 through the amorphous layer and the insulating layer 106, so as to provide a higher crystallization temperature on the portion 110 of the polysilicon layer 108 directly above the reflector 105. That is, the portion 110 of the polysilicon layer 108 directly above the reflector 105 has a grain size greater than that of other portions. Typically, the grain size of the polysilicon material is inversely proportional to the grain-boundary capacitance. Conversely, the grain-boundary capacitance is proportional to the sub-threshold swing. Accordingly, a lower sub-threshold swing can result when the grain size of the polysilicon layer serving as an active layer for a thin film transistor (TFT) is increased. Next, a channel doping process may be optionally performed on the polysilicon layer 108.

In FIG. 1D, the polysilicon layer 108 shown in FIG. 1C is subsequently patterned to form a polysilicon pattern layer 112 overlying the reflector 105 in the driving circuit region D and a polysilicon pattern layer 114 overlying the substrate 100 of the pixel region P. Particularly, the polysilicon pattern layer 112 is substantially aligned to the reflector 105 polysilicon pattern layer 112. The polysilicon pattern layers 112 and 114 serve as first and second active layers for TFTs in the pixel region P and in the driving circuit region D, respectively. Since the first active layer 112 substantially aligned to the reflector 105 is formed at a higher crystallization temperature than that of the formation of the second active layer 114, the first active layer 112 has a grain size greater than that of the second active layer 114.

In FIG. 1E, an insulating layer 116 and a conductive layer (not shown) are successively formed on the first and second active layers 112 and 114 and the insulating layer 106. In this embodiment, the insulating layer 116 serves as a gate dielectric and may be a single layer or multiple layers. For example, the insulating layer 116 may comprise silicon oxide, silicon nitride, or a combination thereof. The insulating layer 116 can be formed by conventional deposition, such as CVD. The conductive layer may comprise metal, such as molybdenum (Mo) or Mo alloy. The conductive layer can be formed by CVD or sputtering. The conductive layer is subsequently etched to form gate layers 118 and 120 overlying the first and second active layers 112 and 114, respectively.

In FIG. 1F, heavy-ion implantation 121 is subsequently performed in the first and second active layers 112 and 114 using the gate layers 118 and 120 as implantation masks. After completion of the heavy-ion implantation 121, a channel region 113a is formed in the first active layer 112 under the gate layer 118 and a pair of source/drain regions 113b is formed in the first active layer 112 and separated by the channel region 113a. A channel region 115a is also formed in the second active layer 114 under the gate layer 120 and a pair of source/drain regions 115b is formed in the second active layer 114 and separated by the channel region 115a. Thus, a thin film transistor device 200 of the invention is complete.

According to the invention, since the second active layer 114 in the pixel regions P has a smaller grain size than that of the first active layer 112 in the driving circuit region D, the pixel TFT can have a higher sub-threshold swing than the driving TFT in the driving circuit region D. Accordingly, the TFT device 200 can have different electrical characteristics in the driving circuit and pixel regions D and P. That is, a relatively high sub-threshold swing for the pixel TFT can be obtained to increase gray scale inversion of display device, thereby providing high contrast ratio for display devices. At the same time, relatively high carrier mobility and relatively low sub-threshold swing for the driving TFT can be obtained, thereby providing fast response.

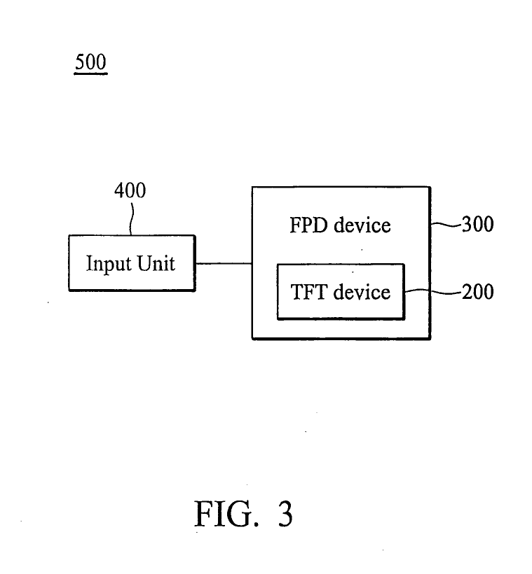

FIG. 3 schematically shows another embodiment of a system for displaying images which, in this case, is implemented as a flat panel display (FPD) device 300 or an electronic device 500 such as a laptop computer, a mobile phone, a digital camera, a personal digital assistant (PDA), a desktop computer, a television, a car display or a portable DVD player. The described TFT device can be incorporated into the flat panel display device 300 that can be an LCD or OLED panel. As shown in FIG. 3, the FPD device 300 may comprise a TFT device, such as a TFT device 200 shown in FIG. 1F or 2. In some embodiments, the TFT device 300 can be incorporated into the electronic device 500. As shown in FIG. 3, the electronic device 500 comprises the FPD device 300 and an input unit 400. Moreover, the input unit 400 is coupled to the FPD device 300 and operative to provide input signals (e.g. image signals) to the FPD device 300 to generate images.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a thin film transistor device, comprising:
a substrate comprising a driving circuit region and a pixel region;
first and second active layers disposed on the substrate in the driving circuit region and in the pixel region, respectively, wherein the first active layer has a grain size greater than that of the second active layer;
two gate structures disposed on the first and second active layers, respectively, wherein each gate structure comprises a stack of a gate dielectric layer and a gate layer; and
a reflector disposed on the substrate under the first active layer and insulated from the first active layer.

2. The system as claimed in claim 1, wherein the first and second active layers comprise low temperature polysilicon.

3. The system as claimed in claim 1, wherein the reflector is insulated from the first active layer by a silicon oxide layer, a silicon nitride layer or a combination thereof.

4. The system as claimed in claim 1, further comprising a buffer layer disposed between the substrate and the first and second active layers, comprising silicon oxide, silicon nitride or a combination thereof.

5. The system as claimed in claim 1, wherein the substrate in the driving circuit region is completely covered by the reflector.

6. The system as claimed in claim 1, wherein the first active layer is substantially aligned to the reflector.

7. The system as claimed in claim 1, wherein the reflector comprises metal.

8. The system as claimed in claim 1, further comprising:
a flat panel display device comprising the transflective thin film transistor device; and
an input unit coupled to the flat panel display device and operative to provide input to the flat panel display device, such that the flat panel display device displays images.

9. The system as claimed in claim 8, wherein the system comprises an electronic device comprising the flat panel display device.

10. The system as claimed in claim 9, wherein the electronic device is a laptop computer, a mobile phone, a digital camera, a personal digital assistant, a desktop computer, a television, a car display or a portable DVD player.

11. A method for fabricating a system for displaying images, wherein the system comprises a thin film transistor device, the method comprising:
providing a substrate comprising a driving circuit region and a pixel region;
forming a reflector on the substrate of the driving circuit region;
forming an insulating layer on the substrate of the driving circuit and pixel regions to cover the reflector;
forming an amorphous layer on the insulating layer;
annealing the amorphous layer by a laser beam having a wavelength of not less than 400 nm, such that the amorphous layer is transformed into a polysilicon layer, wherein the portion of the polysilicon layer directly above the reflector has a grain size greater than that of other portions; and
patterning the polysilicon layer to form a first active layer on the reflector and a second active layer on the substrate of the pixel region.

12. The method as claimed in claim 11, further comprising:
covering each of the first and second active layers by a stack of a gate dielectric layer and a gate layer; and
performing heavy-ion implantation in the first and second active layers, to form a channel region under each of the first and second active layers and form a pair of source/drain regions on both sides of the channel region.

13. The method as claimed in claim 11, wherein the laser beam comprises a solid-state laser beam.

14. The method as claimed in claim 11, wherein the insulating layer comprises a silicon oxide layer, a silicon nitride layer or a combination thereof.

15. The method as claimed in claim 11, further forming a buffer layer between the substrate and the first and second active layers, comprising silicon oxide, silicon nitride or a combination thereof.

16. The method as claimed in claim 11, wherein the substrate in the driving circuit region is completely covered by the formation of the reflector.

17. The method as claimed in claim 11, wherein the first active layer is substantially aligned to the reflector.

18. The method as claimed in claim 11, wherein the reflector comprises metal.
